(19) United States
(12) Patent Application Publication
(10) Pub. No.: US 2026/0343818 A1
(43) Pub. Date: Oct. 29, 2026

(54) DATA CENTER COOLING

(71) Applicant: Schlumberger Technology Corporation, Sugar Land, TX (US)

(72) Inventor: Andrew Clarke, Cambridge (GB)

(21) Appl. No.: 19/311,032

(22) Filed: Aug. 27, 2025

(30) Foreign Application Priority Data
Apr. 28, 2025 (GB) 2506416.3

(51) Int. Cl. H05K 7/20; G06F 1/20

(52) U.S. Cl. CPC H05K 7/20327; G06F 1/20; H05K 7/20809; G06F 2200/201

(57) ABSTRACT

A data center cooling system, for collecting heat at multiple input locations and carrying it to a heat exchanger for discharging the heat, circulates a coolant liquid in which worm-like micelles, which may be viscoelastic surfactant, reduce drag in pipework where the liquid is in a state of inertial turbulence, and the worm-like micelles are disrupted at or adjacent the inlet to the heat exchanger.

### CROSS REFERENCE TO RELATED APPLICATIONS

This application claims priority to GB Patent Application No.: 2506416.3, which was filed on Apr. 28, 20205, and is incorporated herein by reference in its entirety.

### FIELD

This disclosure relates to cooling of electronic components and circuit boards carrying electronic components as used in large numbers in data centers.

### BACKGROUND

A data center typically contains numerous racks of computing equipment containing circuit boards on which there are electronic components which produce heat as they operate. It is conventional that a data center has a combination of systems for cooling these components during operation. One system may contain a circulating coolant liquid which is heated at multiple locations at or close to the racks where the heat is generated and then flows through pipework to a heat exchanger where the heat energy is discharged to another cooling system which carries the heat energy elsewhere, for example, to the environment outside the building.

The coolant used in such system may be an aqueous solution, such as an aqueous solution containing 25% by weight of a glycol. The amount of coolant liquid in such a system may be large. A typical system may have heated solution arriving at the heat exchanger where it will be cooled at a rate of 10 cubic meters (about 2600 US gallons) per minute. A pipe of 35 cm (14 inch) diameter may be used to carry the fluid as it arrives at the heat exchanger. With such a flow rate and pipe size the flow of liquid is turbulent. Within the heat exchanger where the heat energy is transferred to another system which carries it outside the building, the turbulence is advantageous because it enhances heat transfer. However, within the pipework, which may be lengthy, such turbulence is disadvantageous because it dissipates energy which has to be supplied by the pumping system.

It is well known that drag on liquid in a state of turbulent flow through piping can be reduced by adding a drag reducing agent, which is often a polymer. This reduces turbulence adjacent to the pipe wall. However, in a heat exchanger, such reduction of turbulence adjacent to a pipe wall or other fixed surface would reduce the rate of heat transfer and so would be disadvantageous.

### SUMMARY

This summary is provided to introduce concepts that will be further elaborated and described below in the detailed description. This summary is not intended to identify key or essential features of the claimed subject matter, nor is it intended to be used as an aid in limiting the scope of the claimed subject matter.

In a first aspect, the present disclosure provides a method of transferring heat within a data center, comprising pumping a coolant liquid through a system of pipework from one or more heat input locations receiving heat from electronic components to a heat exchanger transferring heat to another system, wherein the coolant liquid is a solution of a compound which spontaneously forms worm-like micelles that reduce resistance to flow at the walls of the pipework, and the method also comprises disrupting the worm-like micelles in the flow arriving at the heat exchanger through the pipework as or before the flow enters the heat exchanger. The method will, in many instances, also include returning the coolant from the heat exchanger through another system of pipework to the heat input locations.

A second aspect of the present disclosure provides a data center heat transfer system comprising pipework configured to provide a flow path for heated liquid from one or more heat inputs receiving heat from computing equipment to a heat exchanger for transferring heat to another system, a coolant liquid, and at least one pump for propelling the liquid through the pipework to the heat exchanger, wherein the coolant liquid is a solution of a compound able to spontaneously form worm-like micelles and the flow path to an inlet of the heat exchanger includes, at or adjacent to the inlet, a component configured to disrupt the worm-like micelles in the flow of coolant.

The formation of wormlike micelles in the liquid circulating along pipework of the heat transfer circuit will reduce drag on the liquid as it flows along the pipe and so reduce the pumping power required to circulate the liquid. The worm-like micelles are believed to reduce turbulence at the periphery of the flow, adjacent to pipe walls. However, within the heat exchanger, a reduction of turbulence adjacent to the pipe walls would reduce the desired transfer of heat energy. Disrupting the micelles as they enter the heat exchanger will mitigate or avoid the reduction of efficiency by intact micelles at the peripheries of flow within the heat exchanger.

Disruption of the micelles may be brought about by a pump which subjects the liquid flowing through the pump to shear. Another possibility is that disruption of worm-like micelles may be brought about by a structure in the pipework which compels the flowing liquid to undergo extensional flow.

When a compound forms wormlike micelles, the connection between molecules of the compound is attraction between molecules. Consequently, the formation and disruption of micelles takes place without breakage of covalent chemical bonds, and micelles can spontaneously reform and resume their action of reducing drag, including reducing drag during return flow to the locations at which the liquid is heated by heat from the electronic components.

A number of chemical compounds spontaneously form wormlike micelles in aqueous solution. Many of these are viscoelastic surfactants and a number of possibilities are set out in T. Saeki “Flow properties and heat transfer of drag reducing surfactant solutions” which is chapter 18 of “Developments in Heat Transfer” edited by D. M. A. D. S. Bernardes, published by InTechOpen, 2011. One possibility mentioned there is cetyl-trimethyl-ammonium chloride in a solution also containing sodium salicylate. Another possibility is stearyl-trimethyl-ammonium chloride which is effective in reducing drag at temperatures up to and above 100 °C. A suitable concentration of the compound to form wormlike micelles may be 10 gm/litre or less, possibly from 1 to 10 or 1 to 5 gm/litre. Such a compound may have a molecular weight not greater than 1000 Daltons.

### BRIEF DESCRIPTION OF THE DRAWINGS

FIG. 1 is a schematic cross section of a data center building.

FIG. 2 is a schematic cross section of a server on line Y-Y of FIG. 3.

FIG. 3 is a cross section on line X-X of FIG. 2.

FIG. 4 is schematic cross section of another data center building.

FIG. 5 is a cross section of a portion of pipework configured to cause extensional flow of liquid entering the heat exchanger.

FIG. 6 is a cross section of the same portion of pipework on the line J-J of FIG. 5

FIG. 7 is a cross section on the line K-K of FIG. 6.

FIG. 8 is a cross section of a portion of pipework also configured to cause extensional flow of liquid entering the heat exchanger.

FIG. 9 is a cross section of a coolant bath, a computing device immersed in the bath and an associated heat exchanger.

FIG. 10 is a schematic cross section of a further data center building.

### DETAILED DESCRIPTION

This detailed description shows various embodiments of the present disclosure and possibilities which may be used. These are given as examples and do not limit this disclosure as defined by the claims. It should be appreciated that features or possibilities described in combination may, where it is practical to do so, be used separately. Also, features or possibilities described in any embodiment may be used in any other embodiment, in so far as it is possible to do so.

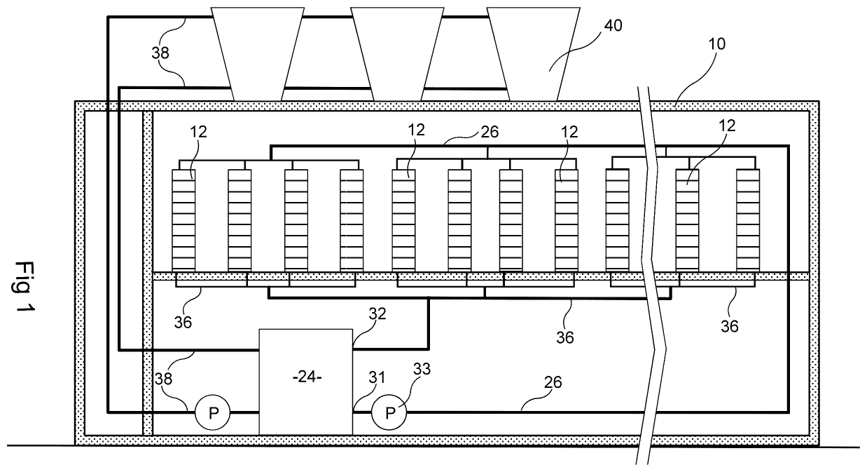

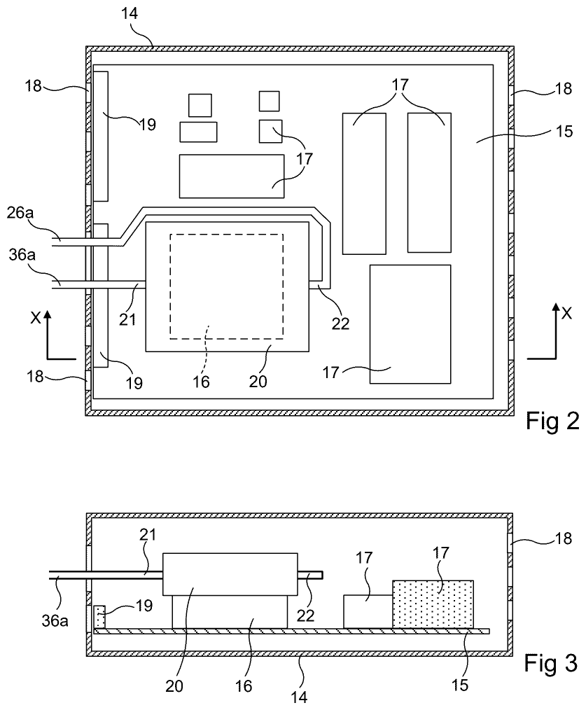

FIG. 1 is a schematic cross section of a two-story building which is a data center 10. The upper story of the building contains a large number of racks 12 each of which contains a number of computing devices, such as servers. One such computing device is shown schematically by FIGS. 2 and 3. It has an outer case 14 inside which is a printed circuit board 15 to which various electronic components are soldered. In this example, the components include a CPU 16 as well as other components 17. The case 14 has openings 18 at opposite ends to allow air to flow through and also to allow electrical connections to connector blocks 19.

In operation the CPU 16 emits heat. Cooling of the CPU is provided by a so-called cold plate 20 which is a hollow vessel made of metal such as copper or aluminum and mounted in direct contact with the CPU 16 so as to allow heat emitted by the CPU to be conducted into the vessel 20. Coolant liquid is supplied to the vessel 20 at inlet 21 and leaves at outlet 22. Many or all of the numerous other computing devices in the racks 12 also have cold plates 20 in them, to collect heat emitted from CPUs, GPUs and other electronic components which emit heat during operation.

The data center has a cooling system embodying the present disclosure. This system includes a large heat exchanger 24. A branching system of pipework 26 connects the outlets 22 of the cold plates 20 to a pump 33 which is located close to the large heat exchanger 24. The pump 33 is connected to the inlet of the large heat exchanger 24. The outlet 32 of the heat exchanger 24 is connected to a pump 33 which is connected to another branching system of pipework 36 for return flow of coolant to the cold plates 20. The large heat exchanger 24 transfers heat energy in the flow from the cold plates 20 to water flowing in another flow circuit 38 which carries the heat to cooling towers 40 on the roof of the data center 10.

The inlet 21 and outlet 22 of each cold plate 20 have small diameter pipes 26a and 36a connected to them. These are part of the branching pipework systerns 26 and 36. The inlet 31 and the outlet 32 of the heat exchanger 24 and the pipes connected to them are of large diameter. The branching systems of pipework 26, 36 may include pipes of intermediate diameters. These branching systems may include components other than pipes. For example, the system 36, which carries return flow from the heat exchanger 24 to the cold plates 20 may include flow controlling valves and/or auxiliary pumps to control the proportions of flow in each of a number of pipes leading from a branch point.

The heat exchanger 24, the pipework systems 26, 36 and the cold plates 20 are filled with a coolant liquid which may be an aqueous solution of a glycol. The pump 33 propels the coolant around the whole system so that heated coolant from the outlets 22 of the cold plates 20 is carried through the pipework system 26 to the pump 33 which propels the flow into the inlet 31 of the heat exchanger and after passing through the heat exchanger 24 return flow of cooled liquid is carried through the pipework 36 to the inlets 21 of the cold plates 20. In the larger diameter pipes of the pipework systems 26, 36 and in particular in the large pipes connected to the pump 33 and outlet 32 of the heat exchanger the coolant may travel at a sufficiently high flow rate that the flow is in a state of inertial turbulence, with a Reynolds number over 2000 (and possibly over 10,000).

In accordance with the present disclosure, the coolant liquid circulating from the cold plates to the heat exchanger 24 and back again contains a small percentage of a viscoelastic surfactant able to form worm-like micelles. These micelles modify the interaction between the coolant and the pipe walls and so enhance the rate of flow or enable use of a less powerful pump than would be required in the absence of the worm-like micelles. However, while this is beneficial in the pipework systems 26, 36 it would reduce thermal contact with surfaces in the heat exchanger and so would be disadvantageous there.

The pump 33 which propels the coolant flow also subjects the coolant liquid to shear, as many pumps do, and because the pump is positioned adjacent to the inlet 31 of the heat exchanger 24 (i.e. slightly upstream from the inlet 31, but close to it) the worm-like micelles are broken up by the shear force on the liquid, just before that liquid enters the heat exchanger 24 through its inlet 31.

It is desirable that the outlet of pump 33 is close to the inlet 31 of the heat exchanger. It may for instance be no more than 2 meters from the heat exchanger inlet 31, possibly no more than 1 meter from the inlet 31.

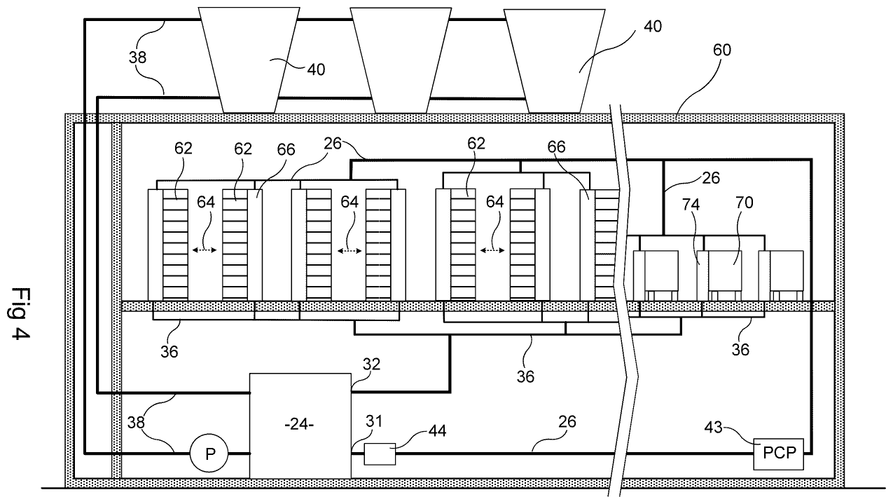

FIG. 4 is a schematic view of a data center which differs from that of FIG. 1. This has a different system for pumping the coolant and disrupting micelles. It also differs in that it uses other methods of collecting heat energy from electronic components which generate heat when they operate. It should be appreciated that the methods of collecting heat energy shown in this FIG. 4 could be used with the cooling system of FIG. 1 and that the collection of heat energy shown in FIG. 1 could be used with the cooling system of this FIG. 4.

The cooling system in this data center has a heat exchanger 24 and pipework systems 26, 36 similar to those shown in FIG. 1. The coolant is a solution of a compound which spontaneously forms worm-like micelles. However, the circulation of the coolant is brought about by a progressive cavity pump 43 which will not apply much shear to the flowing liquid. This is located at a substantial distance from the heat exchanger 24 and the worm-like micelles in the coolant reduce drag as the coolant flows from the pump 43 towards the heat exchanger 24. Just before the coolant arrives at the inlet 31 of the heat exchanger 24, it passes through a structure 44, incorporated in the pipework 26, which compels the liquid to undergo extensional flow, disrupting the worm-like micelles as they enter the heat exchanger 24 through its inlet 31.

One possibility for such a structure is shown in FIGS. 4 to 6. The flow direction is indicated by arrow 46. The portions of the structure indicated as 52 and 53 are cylindrical and have the diameter of the pipework 26 approaching the inlet 31. Between the portions 52 and 53, the portion 56 has a rectangular cross section shown by FIG. 7 and this has a cross sectional area for flow which is less than the cross sectional area of the cylindrical portion 53. This compels the incoming flow to the heat exchanger to accelerate and therefore undergo extensional flow which disrupts the worm-like micelles just before the flow arrives at the inlet 31 of the heat exchanger 24.

It is desirable that the structure 44 to cause extensional flow is located close to the inlet 31 of the heat exchanger. It may for instance be no more than 2 meters from the heat exchanger inlet 31, possibly no more than 1 meter from the inlet 31.

Another possibility for structure to cause extensional flow is shown in FIG. 8. As the pipe approaches the inlet 31 of the heat exchanger 24 it includes a conical portion which accelerates the flow and forms it into a jet. This jet is directed into the heat exchanger 24 and strikes an internal wall 58 within the heat exchanger, thereby creating further extensional flow which disrupts the worm-like micelles.

In part of the upper stories of the building 60 there are racks 62 each of which contains a number of computing devices. These have an outer case 14 inside which there is a printed circuit board to which electronic components 16, 17 are soldered. This is similar to the arrangement shown by FIGS. 2 and 3 except that cold plates are not used.

The racks 12 are arranged in pairs facing each other. To cool the electronic components 16, 17 air is blown into the aisle between each pair of racks 62, for the air to flow into the computing devices in the racks as indicated at 64. At the other side of each rack 62 there is a so-called rear-door heat exchanger 66 which transfers heat energy from the air to a flow of coolant liquid.

The branching pipework systems 26, 36 are connected to the rear door heat exchangers 66 so that heat energy carried by the air flow is transferred to the coolant liquid passing through the heat exchangers 66. It is also possible to locate heat exchangers which transfer heat from the airflow to the coolant liquid at other positions, such as above the racks 62.

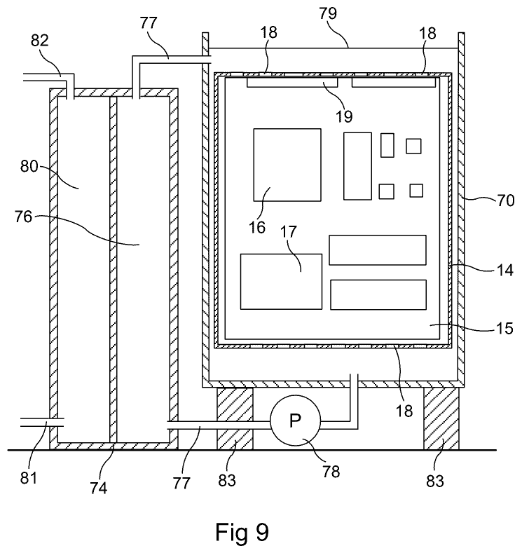

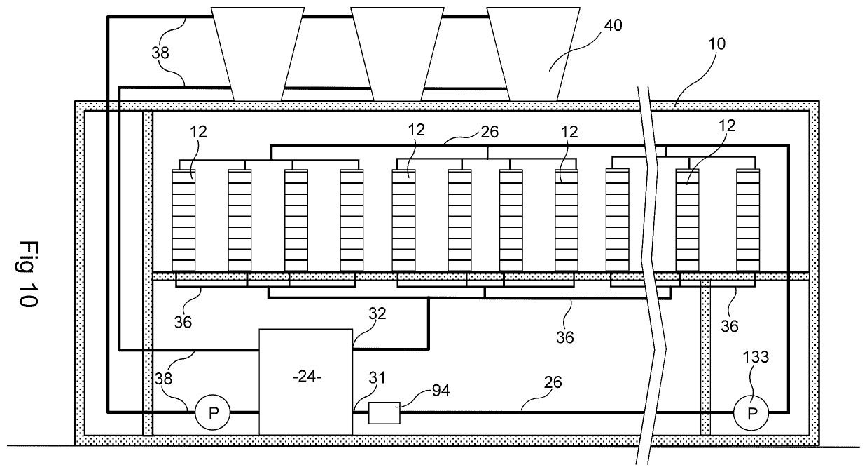

In another part of the upper story of the building 60, computing devices are cooled by immersion in baths 70 of a non-conductive liquid, referred to as dielectric fluid. The position of the baths 70 is indicated in FIG. 4 and one bath is shown by FIG. 9. Each bath 70 is raised on supports 83. Alongside the bath there is a heat exchanger 74 with a chamber 76 connected to the bath 70 by pipes 77 with a pump 78 to circulate dielectric fluid from the bath through the chamber 76. The surface of the dielectric fluid in the bath 70 is indicated at 79. Computing devices with cases 14 are fitted into the bath from above and the dielectric fluid flows upwardly into and through the computing devices. It enters and leaves through the holes 18 in the cases 14.

The inlet 81 of the other chamber 80 of the heat exchanger 74 is connected to the pipework system 36 and the outlet 82 is connected to the pipe work system 26 and so coolant circulated by the pump 43 flows through the chamber 80 of the heat exchanger 74 to collect heat energy from the dielectric fluid.

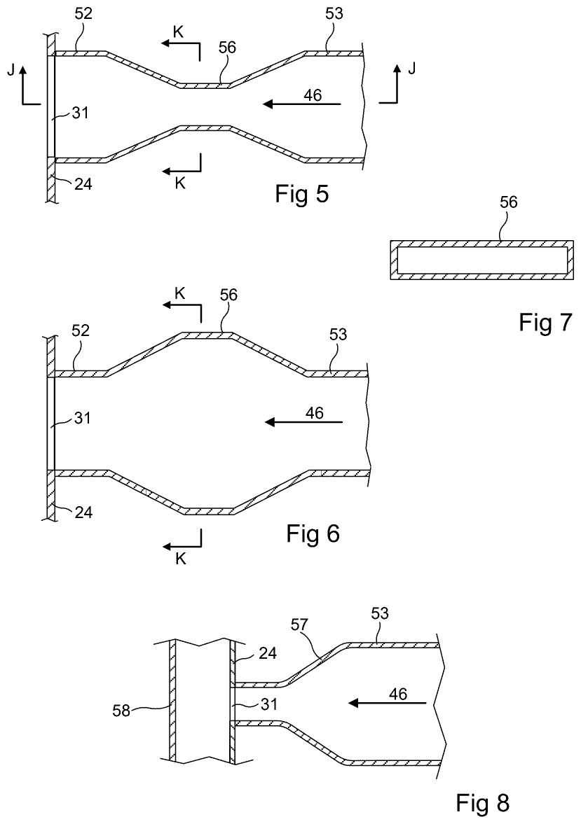

FIG. 10 shows a further data center most of which is the same as the data center shown by FIG. 1. It has a heat exchanger 24 and a pump for circulating coolant. The pump is located a long way from that heat exchanger 24. The coolant liquid includes a viscoelastic surfactant in solution so as to enable worm-like micelles to form spontaneously. A structure 94 is included in the pipework system 26 close to the inlet 31 to the heat exchanger 24. As a result, the flowing coolant forms worm-like micelles in the pipework systems 26, 36 as with the data center shown in FIG. 1, except that these micelles are not yet formed in the pipework 26 for some distance downstream from the pump. The structure 94 may be as described above with reference to FIGS. 5 to 7 or FIG. 8.

In some embodiments of this disclosure, the liquid which circulates through the pipework 26, 36 and the heat exchanger 24 is an emulsion or suspension in which the disperse phase is able to melt and to freeze at a temperature which is above the temperature of cooled liquid flowing out of the heat exchanger 24 and is such that it melts in at least some of the heat input locations, i.e. the cold plates 20, the rear door heat exchangers 66 or the heat exchanger 74. This melting temperature is below a maximum operating temperature for the electronic components which are being cooled by the circulating liquid. This phase change will increase the heat carrying capacity of the circulating liquid because melting of the disperse phase will require the latent heat of fusion of the dispersed material in addition to heat to raise the temperature of the liquid.

As an illustration of this, if a circulating liquid is water and a unit mass of water with specific heat capacity cₚ^{water} is heated from temperature T₁ which is 25 °C to temperature T₂ which is 40 °C the enthalpy change is:

$$Δ {E}^{water} = {c}_{p}^{water} ( {T}_{2} - {T}_{1} )$$

A hypothetical circulating liquid is an emulsion with a continuous phase which is water and a disperse phase which is nonadecane melting to an oil at 32 °C. If unit mass of an emulsion containing proportion φ of the hydrocarbon is heated over the same temperature range, and the melting point of the hydrocarbon is between T₁ and T₂, the enthalpy change is

$$Δ {E}^{pcm} = ϕ ( {L}^{oil} + {c}_{p}^{oil} ( {T}_{2} - {T}_{1} ) ) + ( 1 - ϕ ) {c}_{p}^{water} ( {T}_{2} - {T}_{1} )$$

where L^{oil} is the latent heat of fusion of the hydrocarbon and for simplicity it is assumed that the specific heat of the hydrocarbon is the same for its frozen and liquid forms. In the case of an emulsion containing 30 vol % of nonadecane as the disperse phase in water as continuous phase, and with a temperature rise of 15° between T₁=25 °C and T₂=40 °C spanning the 32 °C melting temperature of the nonadecane, the calculated enthalpy change of the emulsion is approximately twice that of water alone.

Various embodiments of this disclosure have been set out above. These are intended to assist understanding of this disclosure, but not to limit it in any way. It should be appreciated that any features or possibilities described in combination may, where it is practical to do so, be used individually. Also, features or possibilities mentioned in the following claims or described in any embodiment may be used in any other embodiment, in so far as it is practical to do so and where two or more of the following claims are dependent on the same preceding claim, the reader should understand that the present disclosure includes any possible combination of any two or more or all of those dependent claims with each other and also with that preceding claim.

1. A method of transferring heat within a data center, comprising:
pumping a coolant liquid through a system of pipework from one or more heat input locations receiving heat from electronic components to a heat exchanger transferring heat to another system;
wherein the coolant liquid is a solution of a compound which spontaneously forms worm-like micelles that reduce resistance to flow at walls of the pipework; and
disrupting the worm-like micelles in the flow arriving at the heat exchanger through the pipework as or before the flow enters the heat exchanger.

2. The method of claim 1, wherein disrupting the worm-like micelles is by pumping the flow of liquid with a pump located adjacent to an inlet of the heat exchanger.

3. The method of claim 1, wherein the pipework includes a structure, at or adjacent to and upstream of an inlet of the heat exchanger which is shaped to compel the liquid flowing through the structure to undergo extensional flow and thereby disrupts the worm-like micelles as the liquid arrives at the heat exchanger.

4. The method of claim 3, wherein the structure at or adjacent to and upstream of an inlet of the heat exchanger is shaped to reduce a cross-sectional area available for flow and thereby compel the flow to accelerate.

5. The method of claim 3, wherein the structure at or adjacent to and upstream of an inlet of the heat exchanger is configured to form the flow into a jet directed at a target.

6. The method of claim 1, wherein the coolant liquid is an emulsion or suspension comprising a disperse phase which has a melting temperature above a temperature of coolant liquid returning to the one or more heat input locations and which melts at the one or more heat input locations.

7. The method of claim 6, wherein the coolant liquid is an emulsion or suspension in which the disperse phase has a melting temperature in a range from 25 °C to 60 °C.

8. The method of claim 6, wherein the coolant liquid is an aqueous solution and the disperse phase is a hydrocarbon.

9. The method of claim 1, wherein the compound able to form worm-like micelles has a molecular weight not greater than 1000 Daltons.

10. A data center heat transfer system comprising:
pipework configured to provide a flow path for heated liquid from one or more heat inputs receiving heat from computing equipment to a heat exchanger for transferring heat to another system,
a coolant liquid, and
at least one pump for propelling the liquid through the pipework to the heat exchanger;
wherein the coolant liquid is a solution of a compound able to spontaneously form worm-like micelles and the flow path to an inlet of the heat exchanger includes, at or adjacent to the inlet, a component configured to disrupt the worm-like micelles in the flow to the inlet.

11. The system of claim 10, wherein the component is the at least one pump for propelling the liquid through the pipework to the heat exchanger.

12. The system of claim 10, wherein the component comprises a structure which is adjacent to and upstream of the heat exchanger and which is shaped to compel the liquid flowing through the structure to undergo extensional flow.

13. The system of claim 12, wherein the structure at or adjacent to and upstream of the heat exchanger is shaped to reduce a cross-sectional area available for flow and thereby compel the flow to accelerate.

14. The system of claim 12, is configured to form the flow into a jet directed at a target.

15. The system of claim 10, wherein the coolant liquid is an emulsion or suspension comprising a disperse phase which has a melting temperature above a temperature of coolant liquid flowing out of the heat exchanger for return to the one or more heat input locations and which is such that the disperse phase melts at the one or more heat input locations.

16. The system of claim 15, wherein the coolant liquid is an emulsion or suspension in which the disperse phase has a melting temperature in a range from 25 °C to 60 °C.

17. The system of claim 15, wherein the coolant liquid is an aqueous solution and the disperse phase is a hydrocarbon.

18. The system of claim 10, configured for collecting, at a plurality of locations, heat energy generated by computing devices and discharging that energy at the heat exchanger, the system comprising pipework configured for flow of heated liquid from the plurality of locations to the heat exchanger and also comprising pipework for return flow of cooled liquid from the heat exchanger to the plurality of locations.

19. The system of claim 10, wherein the compound able to form worm-like micelles has a molecular weight not greater than 1000 Daltons.
